(19) United States
(12) Patent Application Publication
(10) Pub. No.: US 2025/0183599 A1
(43) Pub. Date: Jun. 5, 2025

(54) METHOD AND SHIELDING ARRANGEMENT FOR SHIELDING CONNECTION PORTION OF CABLE AT A POWER CONVERTER COMPRISING FRAME OR BRACKET, AND THE POWER CONVERTER

(71) Applicant: Vacon Oy, Vaasa (FI)

(72) Inventor: Lasse Aro, Vaasa (FI)

(21) Appl. No.: 18/961,580

(22) Filed: Nov. 27, 2024

(30) Foreign Application Priority Data
Dec. 1, 2023 (DE) 102023133706.8

(51) Int. Cl. H01R 13/6591; H01R 13/6598; H01R 43/033

(52) U.S. Cl. CPC H01R 13/65914; H01R 13/6598; H01R 43/033

(57) ABSTRACT

A method and a shielding arrangement (100) for shielding a connection portion of a cable (10) at a power converter (200) includes a frame or bracket (19). The method includes obtaining (310) an electrically conductive mesh member (12), arranging (320) the electrically conductive mesh member (12) around and along the connection portion and a cable gland (13) on the cable, thereby forming a mesh tube around the connection portion and the cable gland (13), and clamping (330) the electrically conductive mesh member (12) at a first position along the connection portion between a first clamp (14) and the cable (10), and at a second position along the connection portion between a second clamp (20) and a cable gland (13), wherein the electrically conductive mesh member (12) is connected to the frame or bracket (19) via at least one of the first clamp (14) and the second clamp (20). A power converter (200) is also disclosed.

### CROSS-REFERENCE TO RELATED APPLICATION

This application claims foreign priority benefits under 35 U.S.C. § 119 to German Patent Application No. 102023133706.8 filed on Dec. 1, 2023, the content of which is hereby incorporated by reference in its entirety.

### TECHNICAL FIELD

The present invention relates in general to shielding methods and arrangements for cables. In particular, however, not exclusively, the present invention concerns shielding of a connection portion of a cable at a power converter, such as a frequency converter, an inverter, or a rectifier.

### BACKGROUND

There are known solutions developed that provide shielding to cables. It is known that the cable itself can include a screen shield as a common conductive layer around its conductors for electromagnetic shielding/interference (EMC/EMI). The screen may then be connected to ground potential, such as at the power converter to which it is connected to. The screen shield is, however, being stripped away from surroundings of the conductors at a connection portion of the cable which is used to connect to the power converter, thereby exposing the connection portion to potential electromagnetic compatibility (EMC/EMI) related interferences. There is still thus a need to develop shielding solutions to be used at the electric devices.

### SUMMARY

An objective of the present invention is to provide a method and a shielding arrangement for shielding a connection portion of a cable at a power converter comprising a frame or bracket, and a power converter, such as a frequency converter, an inverter, or a rectifier. Another objective of the present invention is that the method and the shielding arrangement make it easier to provide or upgrade shielding, such as EMI/EMC shielding, to a power converter.

The objectives of the invention are reached by a method and a shielding arrangement for shielding a connection portion of a cable at a power converter comprising a frame or bracket, and a power converter, such as a frequency converter, an inverter, or a rectifier, as defined by the respective independent claims.

According to a first aspect, a method for shielding a connection portion of a cable at a power converter comprising a frame or bracket is provided. The method comprises obtaining an electrically conductive mesh member, and arranging the electrically conductive mesh member around and along the connection portion and a cable gland on the cable, thereby forming a mesh tube around the connection portion and the cable gland. The method also comprises clamping the electrically conductive mesh member at a first position along the connection portion between a first clamp and the cable, and at a second position along the connection portion between a second clamp and the cable gland, wherein the electrically conductive mesh member is connected to the frame or bracket via at least one of the first clamp and the second clamp.

The method may also comprise arranging the cable through the cable gland so that the connection portion is on one side of the cable gland and rest of the cable on the opposite side of the cable gland.

Furthermore, both of the first clamp and the second clamp may be coupled to the frame or bracket.

The cable gland may be a grommet, such as a rubber or silicone grommet, attached to the frame or bracket. Thus, the method may comprise attaching the grommet to the frame or bracket.

The first position may be closer to a cable end of the connection portion than the second position. Term “cable end” refers to the part of the connection portion having exposed conductor(s) for connecting to connector(s), such as of the power converter.

The electrically conductive mesh member may be tubular. The method may thus comprise arranging the connection portion through the tubular electrically conductive mesh member before connecting the cable to one or more connectors of the power converter.

The method may comprises wrapping the electrically conductive mesh member around and along the connection portion, for example, if the electrically conductive mesh member is planar, at least after being straightened, that is, before clamping the electrically conductive mesh member with the first and the second clamps. The wrapping should result in portions of the electrically conductive mesh member to overlap so that the cable is completely enclosed in the lateral direction thereof.

There may be a clamping arrangement, comprising the first clamp, a screw for tightening a clamp portion against the cable, which the clamping arrangement is configured for a cable jacket of the cable in a wide range of diameters enabling and ensuring that the cable jacket within the wide range of diameters can still be to be tightened by the clamping arrangement.

According to a second aspect, a shielding arrangement for a connection portion of a cable at a power converter comprising a frame or bracket is provided. The shielding arrangement comprises an electrically conductive mesh member for arranging around and along the connection portion and a cable gland on the cable to form a mesh tube around the connection portion and the cable gland. The shielding arrangement also comprises a first clamp for clamping the electrically conductive mesh member at a first position along the connection portion between a first clamp and the cable, and a second clamp for clamping the electrically conductive mesh member at a second position along the connection portion between a second clamp and the cable gland. The electrically conductive mesh member is connected to the frame or bracket via at least one of the first clamp and the second clamp.

Both of the first clamp and the second clamp may be coupled or be at least couplable to the frame or bracket.

The cable gland may be a grommet, such as a rubber or silicone grommet, attached to the frame or bracket.

The first position may be closer to a cable end of the connection portion than the second position.

The electrically conductive mesh member may be tubular. The method may thus comprise arranging the connection portion through the tubular electrically conductive mesh member before connecting the cable to one or more connectors of the power converter.

The electrically conductive mesh member may be wrapped around and along the connection portion, for example, if the electrically conductive mesh member is planar, at least after being straightened.

According to a third aspect, a power converter is provided. The power converter comprises a frame or bracket, a plurality of switching devices for converting one or more currents and/or voltages, one or more connectors for a cable, and the shield arrangement in accordance with the second aspect.

Optionally, the power converter comprises a cable gland being a grommet, such as a rubber or silicone grommet.

The present invention provides a method and a shielding arrangement for shielding a connection portion of a cable at a power converter comprising a frame or bracket, and a power converter. The present invention provides advantages over known solutions in that it provides a 360-degree shielding of the connection portion of the cable at the power converter. The cost is very low since a piece of electrically conductive mesh member is enough to provide the shielding. Furthermore, the electrically conductive mesh member can easily be used in new installations or to upgrade existing installations.

Various other advantages will become clear to a skilled person based on the following detailed description.

The expression “a number of” may herein refer to any positive integer starting from one (1).

The expression “a plurality of” may refer to any positive integer starting from two (2), respectively.

The terms “first” and “second” etc. are herein used to distinguish one element from another element, and not to specially prioritize or order them, if not otherwise explicitly stated.

The exemplary embodiments of the present invention presented herein are not to be interpreted to pose limitations to the applicability of the appended claims. The verb “to comprise” is used herein as an open limitation that does not exclude the existence of also unrecited features. The features recited in the appended patent claims are mutually freely combinable unless otherwise explicitly stated.

The novel features which are considered as characteristic of the present invention are set forth in particular in the appended claims. The present invention itself, however, both as to its construction and its method of operation, together with additional objectives and advantages thereof, will be best understood from the following description of specific embodiments when read in connection with the accompanying drawings.

### BRIEF DESCRIPTION OF THE DRAWINGS

Some embodiments of the invention are illustrated by way of example, and not by way of limitation, in the figures of the accompanying drawings.

FIGS. 1-6 illustrate schematically a shielding arrangement.

FIG. 7 illustrates electrically conductive mesh members.

FIG. 8 shows a flow diagram of a method.

FIGS. 9A-9C illustrate schematically power converters.

### DETAILED DESCRIPTION

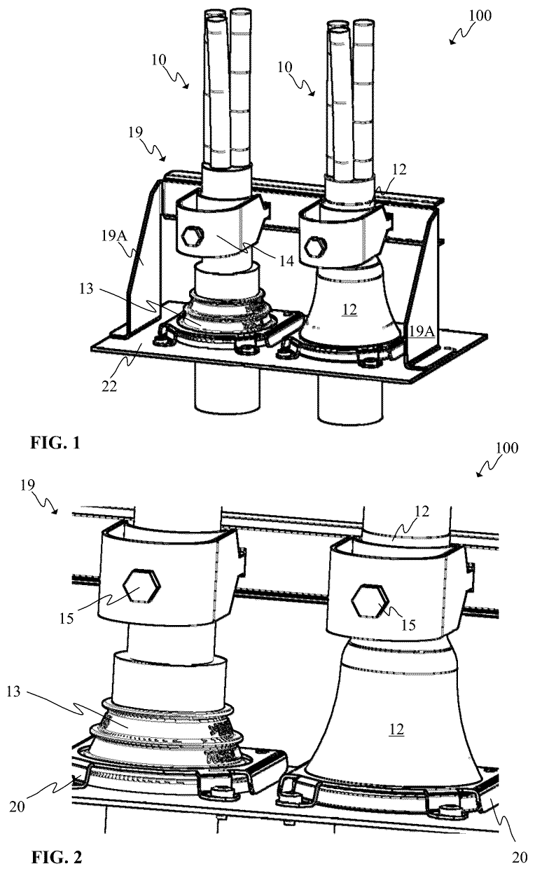

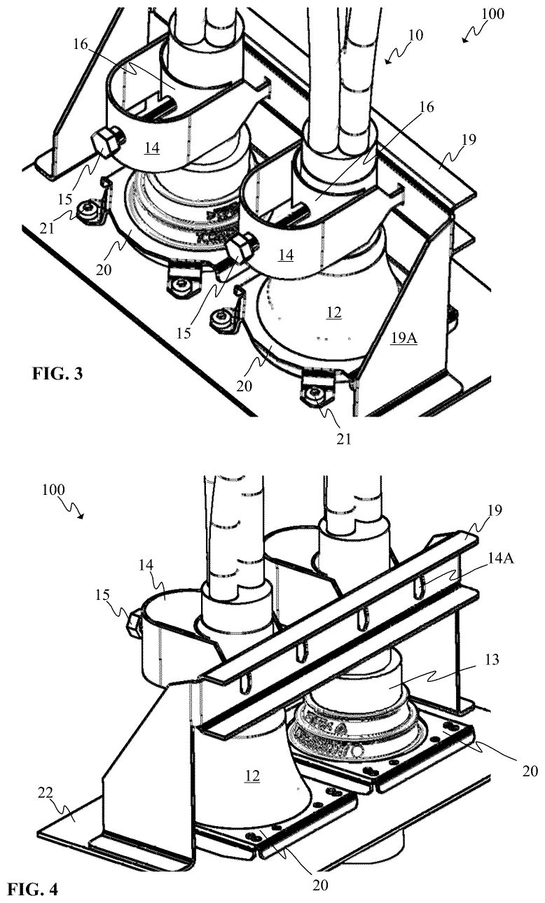

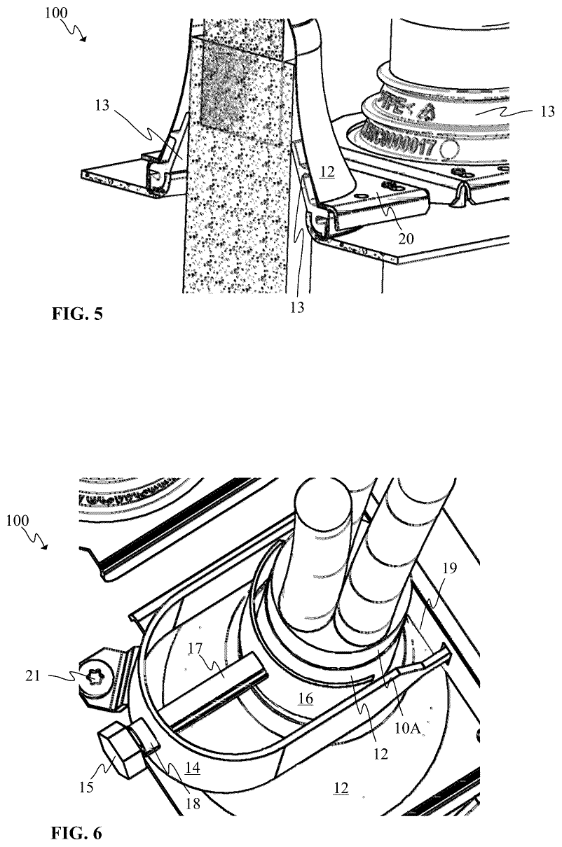

FIGS. 1-6 illustrate schematically a shielding arrangement 100. The shielding arrangement 100 is for a connection portion of a cable 10 at an power converter comprising a frame or bracket 19. The connection portion refers to part of the cable 10 being stripped of some layers, if necessary, to expose the conductors. The frame or bracket 19 is, preferably, in or connected to ground potential and/or enclosure of the power converter and/or to electrical ground or earth on the electrical grid side.

The shielding arrangement 100 comprises an electrically conductive mesh member 12 for arranging around and along the connection portion and a cable gland 13 on the cable 10 to form a mesh tube around the connection portion and the cable gland 13. The shielding arrangement 100 also comprises a first clamp 14 for clamping the electrically conductive mesh member 12 at a first position along the connection portion between a first clamp and the cable 10, such as the cable jacket 10A thereof, and a second clamp 20 for clamping the electrically conductive mesh member 12 at a second position along the connection portion between the second clamp 20 and the cable gland 13. Furthermore, the electrically conductive mesh member 12 is connected to the frame or bracket 19 via at least one of the first clamp 14 and the second clamp 20.

Optionally, the length of the electrically conductive mesh member 12, that is the dimension of the longitudinal direction of the cable 10 around which it is or is to be arranged, is at least three centimeters, preferably in the range of 5-35 centimeters, more preferably in the range of 10-25 centimeters, being, for example, about 20 centimeters.

Distance between the first clamp 14 and the second clamp 20 may be, for example, in range of 2-30 centimeters.

In some cases, both of the first clamp 14 and the second clamp 20 are coupled or couplable to the frame or bracket 19.

Furthermore, the cable gland may be a grommet, such as a rubber or silicone grommet or of other electrically insulating material, attached to the frame or bracket 19.

The first position may be closer to a cable end of the connection portion than the second position, as visible in FIGS. 1-5 which illustrate the first clamp 14 above the second clamp 20.

In some examples, the electrically conductive mesh member 12 is tubular. Thus, it forms a mesh tube which can be arranged around the connection portion and the cable gland 13. The cable 10, or at least the connection portion thereof, may thus need to be arranged through the tubular electrically conductive mesh member 12 before connecting the cable to one or more connectors of the power converter.

In alternative examples, the electrically conductive mesh member 12 may be planar, at least after being straightened. The electrically conductive mesh member 12 may, thus, be wrapped around and along the connection portion.

Furthermore, FIGS. 1-6 illustrate, regarding the frame or bracket 19, that may comprise two plate-like parts linked with a bracket link 19A. The base plate 22, having openings for arranged the cable 10 therethrough, may be comprised in the frame or bracket 19.

Further still, the first clamp 14 may comprise a first clamp portion, such as having a U-shape, attachable to the frame or bracket 19 from ends of the U-shape (may have other shape too, such as V or C or more complex shapes). FIG. 4, illustrating the shielding arrangement 100 from opposite side than FIG. 1, shows clamp attaching portions 14A, or clamp locks, such as including openings, to which the first clamp portion can be attached to. Furthermore, the first clamp 14 may also comprise a second clamp portion 16 which can be tightened by a screw 15 having a shaft 17, such as against a thread 18 of the clamp 14, or the like adjusting mechanism onto the cable 10 so that the electrically conductive mesh member 12 is clamped therebetween at the first position. Thus, the first clamp 14 may comprise several portions and the adjusting mechanism. The clamping arrangement of the clamp 14, the screw 15, the clamp portion 16 ensures that the cable jacket 10A may be in a wide range of diameters which may be tightened by the clamping arrangement.

In some embodiments, thus, a clamping arrangement, that may comprise the first clamp 14, a screw 15 for tightening a clamp portion 16 against the cable 10, that is so that the electrically conductive mesh member 12 is disposed therebetween, is preferably configured for a cable jacket 10A of the cable 10 in a wide range of diameters enabling the cable jackets 10A within the wide range of diameters to be tightened by the clamping arrangement.

Regarding the second clamp 20, it may, in accordance with some embodiments, be a plate-like clamp that can be arranged onto the bottom part of the cable gland 13, thus squeezing the electrically conductive mesh member 12 against the cable gland 13 as clearly visible in FIGS. 1-5. Marked with reference sign 21 is a fastening device, such as a screw, a bolt, or a clip or the like, for locking the second clamp 20 into its place for clamping the electrically conductive mesh member 12 against the cable gland 13.

FIG. 6 shows a cable jacket 10A of the cable 10. Furthermore, FIG. 6 shows how the first clamp 14 has portions extending via openings in the frame or bracket 19.

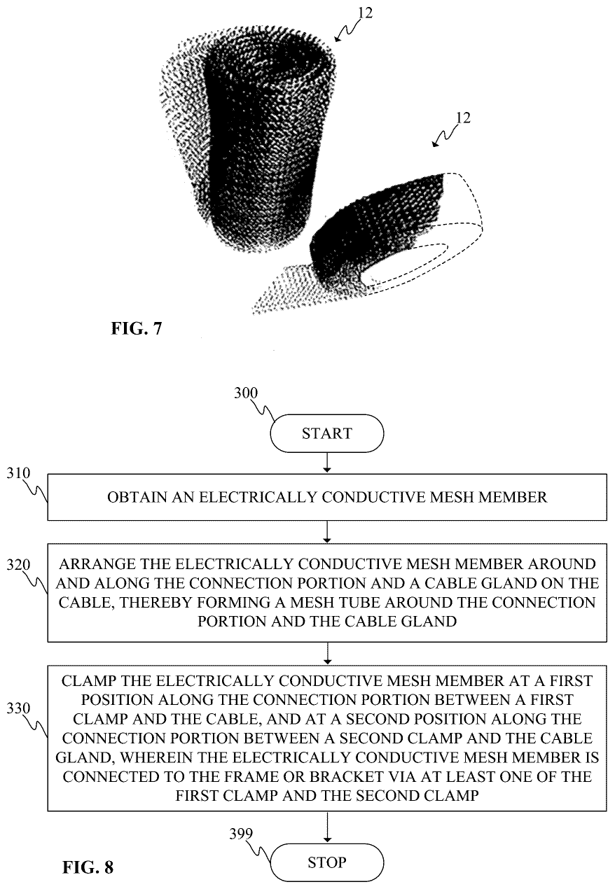

FIG. 7 illustrates electrically conductive mesh members 12, preferably of wire mesh. The electrically conductive mesh members 12 are shown in FIG. 7 as being in mesh rolls from which the member 12 may, optionally, be cut from to exhibit suitable dimensions. The material of the electrically conductive mesh members 12. The mesh rolls in FIG. 7 comprise either tubular mesh or planar mesh. The material of the electrically conductive mesh members 12 may be (stainless) steel, however, may alternatively be of some other electrically conductive material, such as of copper, silver, aluminum, or of some metal alloy. The length of the electrically conductive (wire) mesh member 12 may be as described hereinbefore.

FIG. 8 shows a flow diagram of a method.

Item or step 300 refers to a start-up phase of the method. Suitable equipment and components may be obtained, and systems assembled.

Item or step 310 refers to obtaining an electrically conductive mesh member 12.

Item or step 320 refers to arranging the electrically conductive mesh member 12 around and along the connection portion and a cable gland 13 on the cable 10, thereby forming a mesh tube around the connection portion and the cable gland 13.

Item or step 330 refers to clamping the electrically conductive mesh member 12 at a first position along the connection portion between a first clamp 14 and the cable 10, such as the cable jacket 10A thereof, and at a second position along the connection portion between a second clamp 20 and the cable gland 13, wherein the electrically conductive mesh member 12 is connected to the frame or bracket 19 via at least one of the first clamp 14 and the second clamp 20.

Method execution may be stopped at item or step 399.

The method may also comprise arranging the cable 10 through the cable gland 13 so that the connection portion is on one side of the cable gland 13 and rest of the cable 10 on the opposite side of the cable gland 13.

Furthermore, both of the first clamp 14 and the second clamp 20 may be coupled to the frame or bracket 19.

The cable gland 13 may be a grommet, such as a rubber or silicone grommet, attached to the frame or bracket 19. Thus, the method may comprise attaching the grommet to the frame or bracket 19.

The first position may be closer to a cable end of the connection portion than the second position.

The electrically conductive mesh member 12 may be tubular. The method may thus comprise arranging the connection portion through the tubular electrically conductive mesh member 12 before connecting the cable to one or more connectors of the power converter.

The method may also comprise wrapping the electrically conductive mesh member 12 around and along the connection portion, for example, if the electrically conductive mesh member is planar, at least after being straightened.

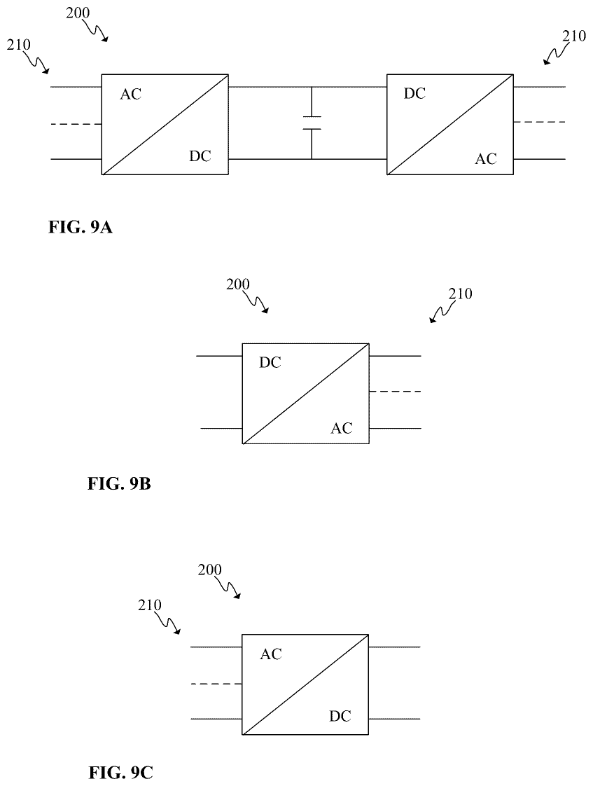

FIGS. 9A-9C illustrate schematically power converters 200. The power converter 200 may be, for example, a frequency converter as shown schematically in FIG. 9A, an inverter as shown in FIG. 9B, or a rectifier as shown in FIG. 9C. The power converter 200 preferably comprises one or more connectors 210 for connecting a cable 10. The power converter 200 may be, for example, a single phase or a three-phase converter device 200, as shown in FIGS. 9A-9C.

As understood by a skilled person in the art, the power converter 200 may comprise also various components not shown and being described herein in detail. For example, the power converter 200 may comprise a controller and various sensors for measuring current(s) and voltage(s), and thereby controlling the operation of the device 200.

The power converter 200 comprises a frame or bracket 19, a plurality of switching devices (not shown in FIGS. 9A-9C, however, included in the symbol with AC/DC or DC/AC as known to a skilled person) for converting one or more currents and/or voltages, and one or more connectors 210 for a cable 10. Furthermore, the power converter 200 also comprise the shield arrangement 100, or any embodiment thereof, as described hereinabove.

In various embodiments, the power converter 200 comprises a cable gland 13 being a grommet, such as of rubber or silicone, and, for example, being attached to the frame or bracket 19.

While the present disclosure has been illustrated and described with respect to a particular embodiment thereof, it should be appreciated by those of ordinary skill in the art that various modifications to this disclosure may be made without departing from the spirit and scope of the present disclosure.

1. A method for shielding a connection portion of a cable at a power converter comprising a frame or bracket, wherein the method comprises:
obtaining an electrically conductive mesh member,
arranging the electrically conductive mesh member around and along the connection portion and a cable gland on the cable, thereby forming a mesh tube around the connection portion and the cable gland, and
clamping the electrically conductive mesh member at a first position along the connection portion between a first clamp and the cable, and at a second position along the connection portion between a second clamp and a cable gland, wherein the electrically conductive mesh member is connected to the frame or bracket via at least one of the first clamp and the second clamp.

2. The method of claim 1, comprising arranging the cable through the cable gland so that the connection portion is on one side of the cable gland and rest of the cable on the opposite side of the cable gland.

3. The method of claim 1, wherein both of the first clamp and the second clamp are coupled to the frame or bracket.

4. The method of claim 1, wherein the cable gland is a grommet attached to the frame or bracket.

5. The method of claim 1, wherein the first position is closer to a cable end of the connection portion than the second position.

6. The method of claim 1, wherein the electrically conductive mesh member is tubular.

7. The method of claim 1, comprises wrapping the electrically conductive mesh member around and along the connection portion.

8. The method of claim 1, wherein a clamping arrangement, comprising the first clamp, a screw for tightening a clamp portion against the cable, is configured for a cable jacket of the cable in a wide range of diameters enabling the cable jacket to be tightened by the clamping arrangement.

9. A shielding arrangement for a connection portion of a cable at a power converter comprising a frame or bracket, wherein the shielding arrangement comprises
an electrically conductive mesh member for arranging around and along the connection portion and a cable gland on the cable to form a mesh tube around the connection portion and the cable gland,
a first clamp for clamping the electrically conductive mesh member at a first position along the connection portion between the first clamp and the cable, and
a second clamp for clamping the electrically conductive mesh member at a second position along the connection portion between the second clamp and the cable gland,
wherein the electrically conductive mesh member is connected to the frame or bracket via at least one of the first clamp and the second clamp.

10. The shielding arrangement of claim 9, wherein both of the first clamp and the second clamp are coupled or couplable to the frame or bracket.

11. The shielding arrangement of claim 9, wherein the cable gland is a grommet attached to the frame or bracket.

12. The shielding arrangement of claim 9, wherein the first position is closer to a cable end of the connection portion than the second position.

13. The shielding arrangement of claim 9, wherein the electrically conductive mesh member is tubular.

14. The shielding arrangement of claim 2, wherein the electrically conductive mesh member is planar.

15. A power converter, comprising
a frame or bracket,
a plurality of switching devices for converting one or more currents and/or voltages,
one or more connectors for a cable, and
the shield arrangement of claim 8.

16. The power converter of claim 15, comprising a cable gland being a grommet.
